(19) United States
(12) Patent Application Publication
(10) Pub. No.: US 2003/0127126 A1
(43) Pub. Date: Jul. 10, 2003

(54) Rechargeable solar battery

(76) Inventor: Tzung-Cheng Yang, Silver Spring, MD (US)

Correspondence Address: TZUNG-CHENG YANG, 13245 TREBLECLEF LANE, SILVER SPRING, MD, 20904, US

(21) Appl. No.: 10/040,350

(22) Filed: Jan. 9, 2002

(51) Int. Cl. H01L 31/00

(52) U.S. Cl. 136/251; 136/291; 136/293; 429/111

(57) ABSTRACT

A device is provided which comprises a solar cell section and a thin film battery section. The solar cell section includes one or more solar cells, which generate electrical power and charge electricity in the thin film battery section when they receive light. The thin film battery section can be attached to or fabricated on the non-light-receiving side of or separated apart from the solar cell section and comprises one or more thin film batteries. This invention eliminates the requirement of using a bulky rechargeable battery to store the energy generated by the solar cell section. Thus, the rechargeable solar battery not only has the recharging capability, it is also thin and light. This invention is very usefully especially for portable devices and solar powered devices.

### CROSS-REFERENCE TO RELATED APPLICATIONS

U.S. Pat. Documents

| | | | |
|---|---|---|---|
| 6005183 | December 1999 | Akai et al. | 136/244 |
| 5886688 | June 1995 | Fifield et al. | 345/206 |
| 5983073 | April 1997 | Ditzik | 455/11.1 |

### STATEMENT REGARDING FEDERALLY SPONSORED RESEARCH OR DEVELOPMENT

Not Applicable

### REFERENCE TO SEQUENCE LISTING, A TABLE, OR A COMPUTER PROGRAM LISTING COMPACT DISK

Not Applicable

### BACKGROUND OF THE INVENTION

The present invention relates to a device containing one or more solar cells and one or more thin film batteries integrally, which is preferable as an electronic power supply or source for many devices such as walkman, battery powered toy, calculator, portable game, beacon generator, watch, and etc.

Solar cells are widely used in view of their energy efficiency and non-maintenance. However, a solar cell can generate electricity only when it receives light such as solar light and so on, it can not generate any power at nighttime and under cloudy or rainy conditions even if it is daytime, power generation is remarkably reduced. Consequently, rechargeable batteries are used to store the electricity generated by the solar cell. However, up to the present time, the rechargeable batteries used to be charged by solar cells are bulky and heavy. With the presented apparatus, the size and weight of the applied device can be greatly reduced.

### BRIEF SUMMARY OF THE INVENTION

This invention integrates one or more thin film batteries and one or more solar cells into the rechargeable solar battery. The rechargeable solar battery can be charged by light. It also has the property of light-weighted and occupies little space. The thin film battery can be manufactured directly on or attached to the non-light-receiving side of the solar cell. One example of the application of the rechargeable solar battery is the light-weighted walkman. When the user wears the light-weighted walkman and jogs under sunlight, the solar cells receive sunlight and generate electricity for the walkman and also store the electricity in the thin film batteries. The light-weighted walkman can function even when the user jogs under shadows or any place without light, because the thin film batteries can supply electricity under such conditions. This kind of feature can not be achieved solely by the solar cells. Also, the thin film batteries can provide more electrical power than just use the solar cells alone. Compared with the walkman used at the present time, the light-weighted walkman has the following advantages. (1) The light-weighted walkman using the presented rechargeable solar battery is lighter and smaller because the rechargeable solar battery is much lighter and thinner than the batteries used at present time. (2) The light-weighted walkman is more economic because it use the sunlight as the energy source and the sunlight is free. (3) The light-weighted walkman is maintenance free since the user does not need to replace the batteries or take rechargeable batteries out to recharge if rechargeable batteries are used. The same advantage can be applied to many other solar-powered devices.

### BRIEF DESCRIPTION OF THE SEVERAL VIEWS OF THE DRAWING

With reference to the drawings:

FIG. 1 shows the front view and the side view of the invention.

FIG. 2 shows the electrical diagram of the invention.

FIG. 3 shows the diagram of the invention when multiple solar cells and multiple thin film batteries are used.

### DETAILED DESCRIPTION OF THE INVENTION

A thin film battery is a kind of battery, which can be as thin as a piece of foil. Thus, the thin film battery is also called foil battery. The thin film battery used in this invention is rechargeable. It can be made by using ceramic Lithium Phosphorus Oxynitride (LiPON) as electrolyte, LiCoO2 as cathode, and Lithium as anode.

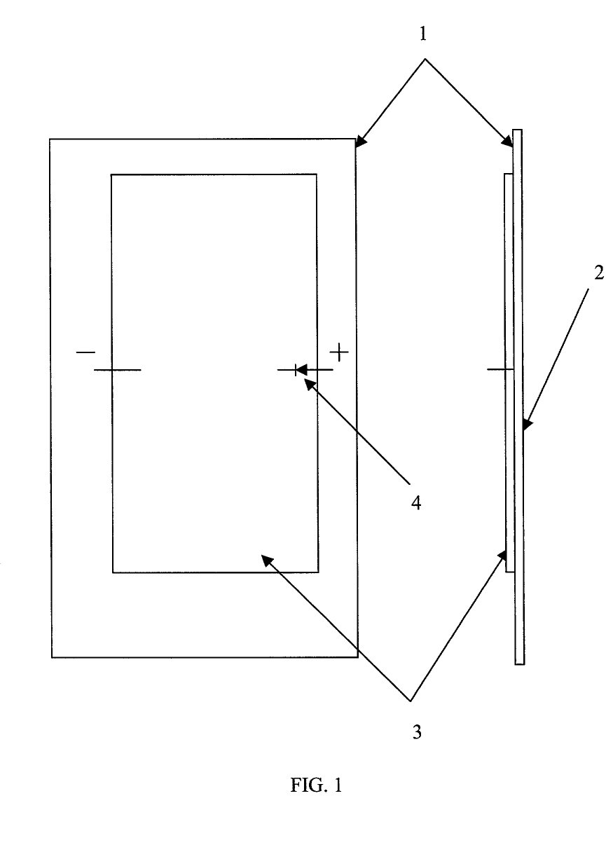

FIG. 1 shows the front view and the side view of the invention with the thin film battery attached to the non-light-receiving side of the solar cell. 1 indicates the solar cell, 2 indicates the light-receiving side of the solar cell, and 3 is the thin film battery. The positive end of the solar cell is connected to the positive end of the thin film battery through a reverse flow preventing diode 4. The negative end of the solar cell is connected to the negative end of the thin film battery.

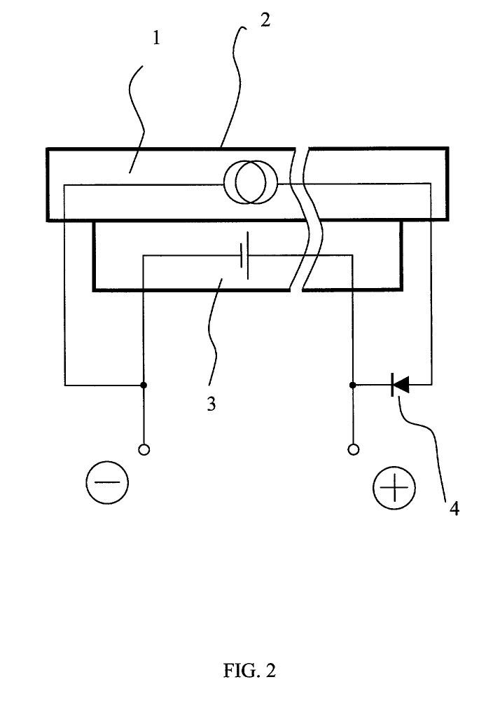

FIG. 2 shows the electrical diagram of the invention. 1 is the solar cell and 3 is the thin film battery with the thin film battery attached to the non-light-receiving side of the solar cell. 2 indicates the light-receiving side of the solar cell. Electrical energy generated by the solar cell can be stored in the thin film battery 3. Diode 4 is the reverse flow preventing diode, which is used to prevent the solar cell from being damaged due to the influence of an electric circuit comprising a load and the battery.

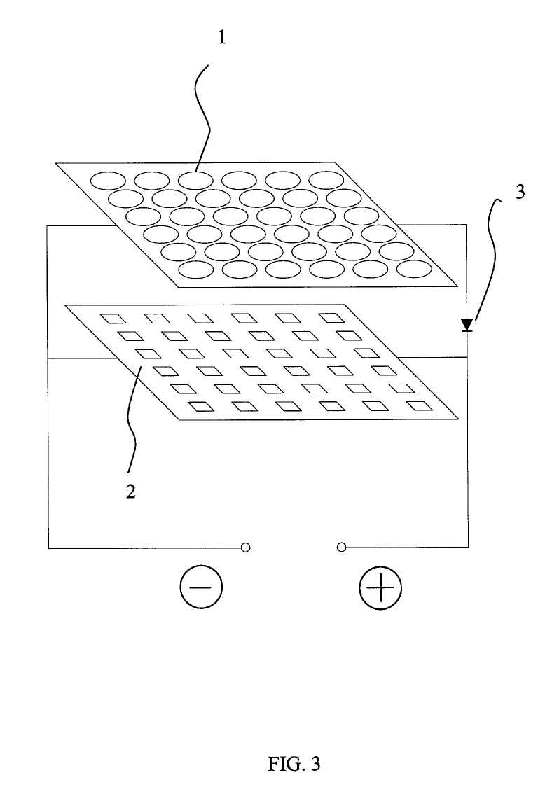

FIG. 3 shows the diagram of the invention when multiple solar cells and multiple thin film batteries are used. 1 is the solar cell section and 2 is the thin film battery section. 3 is the reverse flow preventing diode. To make the circuit effective more than one solar cells can be used to form the solar cell section and more than one thin film batteries can be used to form the thin film battery section. There can be several different kinds of connection methods to construct the solar cell section and the thin film battery section. One way is to connect the solar cells in series to form several serial branches. These serial branches with similar voltage are then connected in parallel to form the solar cell section. The other alternative is to connect the solar cells in parallel to form several parallel branches. These parallel branches are then connected in series to form the solar cell section. Another alternative is to connect the solar cells in a two-dimensional matrix form. Each solar cell in the two-dimensional form is connected in series with one or two other solar cells and is also connected in parallel with one or two different other solar cells. Similarly, for the thin film battery section, one way is to connect the thin film batteries in series to form several serial branches. These serial branches with similar voltage are then connected in parallel to form the thin film battery section. The other alternative is to connect the thin film batteries in parallel to form several parallel branches. These parallel branches are then connected in series to form the thin film battery section. Another alternative is to connect the thin film batteries in a two-dimensional matrix form. Each thin film battery in the two-dimensional form is connected in series with one or two other thin film batteries and is also connected in parallel with one or two different other thin film batteries. The number of the serial connected solar cells and thin film batteries are selected so that the voltage of the solar cell section is compatible with the voltage of the thin film battery section. A reverse current preventing diode is used between the solar cell section and the thin film battery section to protect the solar cells from damage. As long as the thin film batteries and the solar cells are electrically connected, they can be arranged in any place of the applied device. The thin film battery can be attached to the non-light-receiving side of the solar cell. It can also be fabricated directly on the non-light-receiving side of the solar cell. On a similar manner, the solar cell can also be fabricated directly on the thin film battery. The solar cell and the thin film battery can also be arranged in a manner that they separate apart with each other.

What I claim as my invention is:

1. A device containing a solar cell section and a thin film battery section comprising:
a solar cell section comprising one or more solar cells which generate electrical power when they receive light; and
a thin film battery section attached to, fabricated on, or separated apart from the solar cell section, comprising one or more thin film batteries.

2. A device as set forth in claim 1, wherein said device is formed as a module or as a whole.

3. A device as set forth in claim 1, further comprising an electric circuit for charging electrical power generated by said solar cell section in said thin film battery section and for providing electrical power to output terminals of said device.

4. A device as set forth in claim 3, wherein said electric circuit includes first and second pairs of lines formed inside said device, said first pair of lines are connected to provide the electrical power from said solar cell section to said output terminals, and said second pair of lines are connected to charge the electrical power from said solar cell section to said thin film battery section and to provide the charged electrical power to said output terminals.

5. A device as set forth in claim 4, wherein said first and second pairs of lines are connected to each other prior connecting to said output terminals, and said electric circuit further includes a diode for preventing a reverse current flowing through said first pair of lines, which is imposed in one of lines of said first pair.

6. A device as set forth in claim 1, wherein said solar cells are connected such that they are connected in series for several ones to form serial branches providing substantially the same voltage and said serial branches are connected in parallel, and the number of said solar cells of each of said serial branches is selected so that the voltage provided by said serial branches is substantially the same as that of said thin film battery section.

7. A device as set forth in claim 1, wherein said thin film batteries are connected such that they are connected in series for several ones to form serial branches providing substantially the same voltage and said serial branches are connected in parallel, and the number of said thin film batteries of each of said serial branches is selected so that the voltage provided by said serial branches is substantially the same as that of said solar cell section.

8. A device as set forth in claim 1, wherein said solar cells can also be connected such that they are connected in parallel for several ones to form parallel branches and said parallel branches are connected in series, and the number of said parallel branches is selected so that the voltage provided by said solar cell section is substantially the same as that of said thin film battery section.

9. A device as set forth in claim 1, wherein said thin film batteries can also be connected such that they are connected in parallel for several ones to form parallel branches and said parallel branches are connected in series, and the number of said parallel branches is selected so that the voltage provided by said thin film battery section is substantially the same as that of said solar cell section.

10. A device as set forth in claim 1, wherein said solar cells can also be connected such that each solar cell is connected in series with one or two other solar cells and is also connected in parallel with one or two different other solar cells to make a two-dimensional matrix form, and the number of series-connected solar cells is selected so that the voltage provided by said solar cell section is substantially the same as that of said thin film battery section.

11. A device as set forth in claim 1, wherein said thin film batteries can also be connected such that each thin film battery is connected in series with one or two other thin film batteries and is also connected in parallel with one or two different other thin film batteries to make a two-dimensional matrix form, and the number of series-connected thin film batteries is selected so that the voltage provided by said thin film battery section is substantially the same as that of said solar cell section.
